(19) United States
(12) Patent Application Publication
(10) Pub. No.: US 2017/0233613 A1
(43) Pub. Date: Aug. 17, 2017

(54) ADHESIVE TAPES AND HEAT SPREADER ASSEMBLIES

(71) Applicant: Avery Dennison Corporation, Glendale, CA (US)

(72) Inventor: Josh M. BOGNER, Mentor, OH (US)

(21) Appl. No.: 15/502,650

(22) PCT Filed: Aug. 18, 2015
(86) PCT No.: PCT/US15/45642

§ 371 Date: Feb. 8, 2017

Related U.S. Application Data
(60) Provisional application No. 62/053,959, filed on Sep. 23, 2014.
(60) Provisional application No. 62/042,712, filed on Aug. 27, 2014.
(60) Provisional application No. 62/038,456, filed on Aug. 18, 2014.

(51) Int. Cl. C09J 7/02; F28F 21/08; C09J 9/00; H01L 23/373; C09J 133/00; C09J 9/02

(52) U.S. Cl. CPC C09J 7/0292; C09J 7/0246; C09J 133/00; C09J 9/02; C09J 9/00; H01L 23/3735; H01L 23/3737; F28F 21/081; C09J 2433/00; C09J 2400/163; F28F 2275/025

(57) ABSTRACT

Adhesive tapes including a thin metal foil layer are described. The tapes also include a layer or one or more regions of a pressure sensitive adhesive. The tapes exhibit a high thermal conductivity and find application as heat transfer components. Also described are heat spreader assemblies using the adhesive tapes.

### CROSS-REFERENCE TO RELATED APPLICATION

The present application claims the benefit of U.S. Provisional Application No. 62/038,456 filed Aug. 18, 2014, U.S. Provisional Application No. 62/042,712 filed on Aug. 27, 2014, and U.S. Provisional Application No. 62/053,959 filed Sep. 23, 2014, which are all incorporated herein by reference in their entireties.

### FIELD

The present subject matter relates to single sided and double sided adhesive tapes which are electrically and thermally conductive. In certain applications, the tapes can be used as flexible and bondable heat spreaders. The present subject matter also relates to heat spreader assemblies using one or both of the tapes.

### BACKGROUND

Many electronic assemblies utilize cooling components such as heat sinks and fans. In certain applications “heat spreaders” as known in the art can be used to dissipate heat that is generated in one or more regions of an assembly or other environment. Heat spreaders are commonly used within electronic enclosures to transfer heat from discrete components to the walls of the enclosure.

Heat spreaders can be formed from metals such as copper or natural graphite materials. Heat spreaders have also been formed from carbon fabrics, other coated fabrics, carbon paper, and the like. The use of metal-composite materials as heat spreaders is also known.

Heat spreaders in the form of graphite-containing adhesive tapes are also known. Such tapes typically utilize a core of polyethylene terephthalate (PET) to provide dimensional stability and reinforce an otherwise weak interlayer strength of graphite. Although satisfactory in many respects, a need remains for an improved heat spreader which has a relatively high thermal conductivity, includes an adhesive face for secure and reliable bonding, and which can be economically manufactured.

### SUMMARY

The difficulties and drawbacks associated with previous approaches are addressed in the present subject matter as follows.

In one aspect, the present subject matter provides an adhesive tape comprising a metallic foil layer. The foil layer includes at least one agent selected from the group consisting of aluminum, copper, gold, silver, beryllium, tungsten, alloys thereof, and combinations thereof. The foil layer defines a first face and an oppositely directed second face. The tape also comprises a layer of adhesive disposed on and immediately adjacent to the first face of the foil layer. The layer of adhesive is free of conductive agents.

In another aspect, the present subject matter provides an adhesive tape comprising a layer of adhesive and a metallic foil layer exhibiting a thermal conductivity greater than 100 W/mK at 25° C. The foil layer is disposed immediately adjacent to and in contact with the layer of adhesive. The layer of adhesive has a thickness less than 10 microns.

In another aspect, the present subject matter provides a method of increasing heat transfer from a first location having a first temperature to a second location having a second temperature less than the first temperature. The method comprises providing an adhesive tape including (i) an inner metallic foil layer, the foil layer including at least one agent selected from the group consisting of aluminum, copper, gold, silver, beryllium, tungsten, alloys thereof, and combinations thereof, the foil layer defining a first face and an oppositely directed second face, and (ii) a layer of adhesive free of conductive agents and disposed on the first face of the foil layer. The method also comprises applying the adhesive tape on both of the first location and the second location.

In still another aspect, the present subject matter provides a method of transferring heat from a first location to a second location having a temperature lower than that of the first location. The method comprises adhering an adhesive tape between the first location and the second location wherein the adhesive tape includes a layer of adhesive, and a metallic foil layer exhibiting a thermal conductivity greater than 100 W/mK at 25° C. The foil layer is disposed immediately adjacent to the layer of adhesive. And the foil layer in contact with the layer of adhesive. The foil layer has a thickness within a range of from 5 microns to 15 microns.

In another aspect, the present subject matter provides an adhesive tape comprising an inner metallic foil layer. The foil layer includes at least one agent selected from the group consisting of aluminum, copper, gold, silver, beryllium, tungsten, alloys thereof, and combinations thereof. The foil layer defines a first face and an oppositely directed second face. The adhesive tape also comprises a first layer of adhesive disposed on the first face of the foil layer, and a second layer of adhesive disposed on the second face of the foil layer. The adhesive layers are free of conductive agents.

In another aspect, the present subject matter provides an adhesive tape comprising a first layer of adhesive, a second layer of adhesive, and a metallic foil layer exhibiting a thermal conductivity greater than 100 W/mK at 25° C. The foil layer is disposed between the first layer of adhesive and the second layer of adhesive. And the foil layer is in contact with both the first layer of adhesive and the second layer of adhesive. Each adhesive layer has a thickness less than 10 microns.

In still another aspect, the present subject matter provides a method of increasing heat transfer from a first location having a first temperature to a second location having a second temperature less than the first temperature. The method comprises providing an adhesive tape including (i) an inner metallic foil layer, the foil layer including at least one agent selected from the group consisting of aluminum, copper, gold, silver, beryllium, tungsten, alloys thereof, and combinations thereof, the foil layer defining a first face and an oppositely directed second face, (ii) a first layer of adhesive free of conductive agents disposed on the first face of the foil layer, and (iii) a second layer of adhesive free of conductive agents disposed on the second face of the foil layer. The method also comprises applying the adhesive tape on both of the first location and the second location.

In yet another aspect, the present subject matter provides a method of transferring heat from a first location to a second location having a temperature lower than that of the first location. The method comprises adhering an adhesive tape between the first location and the second location. The adhesive tape includes a first layer of adhesive, a second layer of adhesive, and a metallic foil layer exhibiting a thermal conductivity greater than 100 W/mK at 25° C. The foil layer is disposed between the first layer of adhesive and the second layer of adhesive and the foil layer is in contact with both the first layer of adhesive and the second layer of adhesive. The foil layer has a thickness within a range of from 4 to 20 microns.

In still another aspect, the present subject matter provides a heat spreader assembly comprising a heat conductive member defining a first face and an oppositely directed second face. The heat spreader assembly also comprises an adhesive tape including (i) a metallic foil layer, the foil layer including at least one agent selected from the group consisting of aluminum, copper, gold, silver, beryllium, tungsten, alloys thereof, and combinations thereof, the foil layer defining a first face and an oppositely directed second face, and (ii) a layer of adhesive disposed on and immediately adjacent to the first face of the foil layer, wherein the layer of adhesive is free of conductive agents. The layer of adhesive of the adhesive tape is in contact with a face of the heat conductive member. In further aspects, the heat spreader assembly can also additionally comprise other adhesive tapes such as any of the tapes described herein.

In yet another aspect, the present subject matter provides a heat spreader assembly comprising a heat conductive member defining a first face and an oppositely directed second face. The heat spreader assembly also comprises an adhesive tape including (i) a first layer of adhesive, (ii) a second layer of adhesive, and (iii) a metallic foil layer exhibiting a thermal conductivity greater than 100 W/mK at 25° C., the foil layer disposed between the first layer of adhesive and the second layer of adhesive and the foil layer in contact with both the first layer of adhesive and the second layer of adhesive, wherein each of the first and the second layers of adhesive has a thickness less than 10 microns. The first layer of adhesive of the adhesive tape is in contact with a face of the heat conductive member. In further aspects, the heat spreader assembly can also additionally comprise other adhesive tapes such as any of the tapes described herein.

In still another aspect, the present subject matter provides a heat spreader assembly comprising a heat conductive member having a first face and an oppositely directed second face. The heat spreader assembly also comprises a single sided adhesive tape including a metallic foil layer and a layer of adhesive. The layer of adhesive is in contact with the first face of the heat conductive member. The heat spreader assembly also comprises a double sided adhesive tape including two layers of adhesive and a metallic foil layer disposed between the two adhesive layers. One of the two adhesive layers is in contact with the second face of the heat conductive member.

As will be realized, the subject matter described herein is capable of other and different embodiments and its several details are capable of modifications in various respects, all without departing from the claimed subject matter. Accordingly, the drawings and description are to be regarded as illustrative and not restrictive.

### BRIEF DESCRIPTION OF THE DRAWINGS

FIG. 1 is a schematic cross sectional view of an adhesive tape embodiment in accordance with the present subject matter.

FIG. 2 is a schematic cross sectional view of another adhesive tape embodiment in accordance with the present subject matter.

FIG. 3 is a schematic cross sectional view of another adhesive tape embodiment in accordance with the present subject matter.

FIG. 4 is a schematic cross sectional view of another adhesive tape embodiment in accordance with the present subject matter.

FIG. 5 is a schematic cross sectional view of a heat spreader assembly in accordance with the present subject matter.

FIG. 6 is a schematic cross sectional view of another heat spreader assembly in accordance with the present subject matter.

FIG. 7 is a schematic cross sectional view of another heat spreader assembly in accordance with the present subject matter.

### DETAILED DESCRIPTION OF THE EMBODIMENTS

Generally, the present subject matter relates to single sided and double sided adhesive tapes which are electrically and thermally conductive, provide electromagnetic interference (EMI) and radio frequency interference (RFI) shielding, and have a significantly higher thermal conductivity than many conventional tapes. The single sided tape includes (i) a layer of a metal foil, and (ii) an adhesive layer on a face of the foil. The double sided tape includes (i) an inner layer of a metal foil, (ii) a first adhesive layer on one face of the foil, and (iii) a second adhesive layer on an opposite face of the foil.

The present subject matter also relates to heat spreader assemblies using one or both of the single sided tape and the double sided tape.

### Adhesive Tapes

### Metal Foil

The adhesive tapes comprise a metal layer which is in the form of a metal foil. The metallic foil can be formed from one or more metals, their alloys, and/or their oxides, which are electrically conductive and thermally conductive. A wide array of metals can be included in the metal foil so long as the selected metal(s) exhibits a thermal conductivity greater than 100 W/mK at 25° C., more particularly greater than 150 W/mK at 25° C., and in certain embodiments greater than 170 W/mK at 25° C. Nonlimiting examples of suitable metals include copper, aluminum, gold, silver, beryllium, tungsten, oxides thereof, alloys thereof, and combinations thereof. In many embodiments, the metal foil includes aluminum or copper. It will be understood that the present subject matter includes the use of other metals and/or materials for use as the foil layer so long as that layer exhibits the noted thermal conductivity. The metal foil layer is typically opaque which may be desirable for certain applications such as those involving printing on the metal face.

In many embodiments of the present subject matter, the metal layer is electrodeposited (ED) metal. Forming metal layers by electrodeposition enables formation of high purity metal layers or foils, and enables precise control of characteristics and properties of the deposited layer.

The metal foil has a thickness of from about 4 to about 20 microns, and in particular embodiments such as for single sided tapes within a range of from 5 to 15 microns and for double sided tapes, within a range of from 6 to 12 microns. However, it will be appreciated that the present subject matter is not limited to the use of metal foils having these thicknesses. Instead, the present subject matter includes the use of foils having thicknesses less than 4 microns and/or greater than 20 microns.

### Adhesive

The adhesive tapes generally include an adhesive layer or regions of adhesive that constitute an adhesive layer. In many embodiments, the tapes comprise a layer of adhesive on one face or both faces of the metal foil. Although the present subject matter is primarily directed to tapes having a continuous adhesive layer, the subject matter includes tapes having a non-continuous adhesive layer.

The adhesive layer or adhesive region(s) can include a wide range of adhesive types and adhesive compositions. In many embodiments, the composition of the adhesive layer is the same or substantially the same throughout the layer or region(s) of adhesive. However, the present subject matter includes tapes having two or more adhesive regions which differ in composition.

A wide array of adhesives and/or adhesive types can be used as the adhesive or adhesive component in the adhesive layer. The adhesive component may be selected from any of a variety of materials, such as acrylics, polyurethanes, thermoplastic elastomers, block copolymers, polyolefins, silicones, rubber based adhesives, and blends of two or more of the foregoing. In many embodiments, the adhesive component is an acrylate adhesive. Nonlimiting examples of monomers and oligomers for inclusion in the acrylate adhesive component are described herein. In many embodiments, the adhesive component is a pressure sensitive adhesive (PSA). A description of useful pressure sensitive adhesive may be found in Encyclopedia of Polymer Science and Engineering, Vol. 13, Wiley-Interscience Publishers (New York, 1988). Additional description of useful PSAs may be found in Encyclopedia of Polymer Science and Technology, Vol. 1, Interscience Publishers (New York, 1964).

A particular acrylate adhesive for use as the adhesive component in the adhesive formulation of the present subject matter is set forth below in Table 1.

TABLE 1
Acrylate Adhesive Component

| Component | Typical |
|---|---|
| Unsaturated Carboxylic Acids | 0.1-10% |
| Crosslinker | 0.1-3% |
| Alkyl Acrylates | 35-95% |
| Acetate Esters | 20-55% |
| Diketones | 0.1-5% |
| Solvent | 10-45% |
| Antioxidant | 0.1-1% |
| Initiator | 0.01-1% |
| TOTAL | 100% |

In certain embodiments, the acrylic polymers for the pressure sensitive adhesive layer(s) include those formed from polymerization of at least one alkyl acrylate monomer containing from about 4 to about 12 carbon atoms in the alkyl group, and present in an amount from about 35-95% by weight of the polymer or copolymer, as disclosed in U.S. Pat. No. 5,264,532. Optionally, the acrylic based pressure sensitive adhesive might be formed from a single polymeric species.

In one embodiment, the pressure sensitive adhesive comprises an acrylic adhesive such as those that are homopolymers, copolymers or cross-linked copolymers of at least one acrylic or methacrylic component. In many embodiments, the adhesive layer exclusively includes acrylic adhesive(s), and thus consist essentially of such adhesives. Examples include acrylic esters such as methyl acrylate, ethyl acrylate, n-propyl acrylate, isopropyl acrylate, n-butyl acrylate, isobutyl acrylate, tert-butyl acrylate, amyl acrylate, hexyl acrylate, octyl acrylate, 2-ethylhexyl acrylate, undecyl acrylate or lauryl acrylate, and optionally as a comonomer, a carboxyl-containing monomer such as (meth)acrylic add [the expression “(meth)acrylic” add denotes acrylic add and methacrylic acid], itaconic add, crotonic add, maleic add, maleic anhydride or butyl maleate, a hydroxyl-containing monomer such as 2-hydroxyethyl(meth)acrylate, 2-hydroxypropyl(meth)acrylate or allyl alcohol, an amido-containing monomer such as (meth)acrylamide, N-methyl(meth)acrylamide, or N-ethyl-(meth)acrylamide, a methylol group-containing monomer such as N-methylol(meth)acrylamide or dimethylol(meth)acrylamide, an amino-containing monomer such as aminoethyl(meth)acrylate, dimethylaminoethyl(meth)acrylate or vinylpyridine, or a non-functional monomer such as ethylene, propylene, styrene or vinyl acetate; mixtures thereof, and adhesives containing at least one such adhesive as a main component.

Many embodiments of the present adhesive formulations comprise one or more tackifiers. Nonlimiting examples of tackifiers include FORAL 85 Resin, available from Pinova. Tackifiers are generally hydrocarbon resins, wood resins, rosins, rosin derivatives, and the like. It is contemplated that any tackifier known by those of skill in the art to be compatible with adhesive formulations may be used with the present subject matter. One such tackifier, found useful is WINGTAK 10, a synthetic polyterpene resin that is liquid at room temperature, and sold by the Goodyear Tire and Rubber Company of Akron, Ohio. WINGTAK 95 is a synthetic tackifier resin also available from Goodyear that comprises predominantly a polymer derived from piperylene and isoprene. Other suitable tackifying additives may include ESCOREZ 1310, an aliphatic hydrocarbon resin, and ESCOREZ 2596, a C₅-C₈ (aromatic modifier aliphatic) resin, both manufactured by Exxon of Irving, Tex.

In many embodiments of the present subject matter, the adhesive component is curable and thus able to undergo crosslinking as known in the art. For such embodiments, the adhesive formulation typically comprises one or more crosslinkers or crosslinking agents. The crosslinker(s) are typically selected based upon the adhesive component. An example of a typical crosslinker for acrylate adhesives is aluminum acetyl acetonate (AAA).

The adhesive formulations may also comprise one or more antioxidants. Nonlimiting examples of such antioxidants include ULTRANOX 626 commercially available from various suppliers.

The adhesive formulations in many embodiments may optionally also comprise one or more liquid vehicles or solvents. The liquid vehicle(s) is typically an organic vehicle, however the present subject matter includes aqueous agents such as water and alcohols. A nonlimiting example of an organic vehicle is toluene. However, it will be appreciated that the present subject matter includes the use of other vehicles and/or solvents in addition to, or instead of, toluene. The liquid vehicle or solvent is typically used as a processing aid. For example, selective addition of the vehicle to the adhesive formulation is used to adjust the viscosity of the adhesive formulation such as prior to depositing the formulation. A nonlimiting example of a weight ratio of liquid vehicle such as toluene that is combined with the adhesive formulation is 60/40 to 5/95, and more particularly 50/50 to 10/90, of liquid vehicle to adhesive formulation, respectively. Additional details and aspects of components of the adhesive formulation are described herein.

The adhesive formulations typically also comprise one or more polymerization initiators. The selection of the initiator(s) is typically based upon the components of the formulation. A nonlimiting example of a suitable initiator is 2,2′-azobis(2-methylbutyronitrile). This initiator is commercially available from several suppliers under the designation VAZO 67.

In certain embodiments, the adhesive may also comprise one or more fillers and/or pigments. Combinations of fillers/pigments may be used. The filler may include carbon black, calcium carbonate, titanium dioxide, day, diatomaceous earth, talc, mica, barium sulfate, aluminum sulfate, silica, or mixtures of two of more thereof. A wide array of organic fillers could be used. Nearly any conventional pigment can be used.

In another embodiment, a useful filler combination includes an anti-blocking agent, which is chosen depending on the processing and/or use conditions. Examples of such agents include for example silica, talc, diatomaceous earth, and any mixtures thereof. The filler particles may be finely divided substantially water-insoluble inorganic filler particles.

The finely divided substantially water-insoluble inorganic filler particles can include particles of metal oxides. The metal oxide constituting the particles may be a simple metal oxide (i.e., the oxide of a single metal) or it may be a complex metal oxide (i.e., the oxide of two or more metals). The particles of metal oxide may be particles of a single metal oxide or they may be a mixture of different particles of different metal oxides.

Examples of suitable metal oxides include alumina, silica, and titania, Other oxides may optionally be present in minor amount, Examples of such optional oxides include, but are not limited to, zirconia, hafnia, and yttria. Other metal oxides that may optionally be present are those which are ordinarily present as impurities such as for example, iron oxide.

When the particles are particles of alumina, most often the alumina is alumina monohydroxide. Particles of alumina monohydroxide, AlO(OH), and their preparation are known.

The adhesive can comprise additional components such as, but not limited to, plasticizer oils, flame retardants, UV stabilizers, optical brighteners, and combinations thereof.

The fillers, pigments, plasticizers, flame retardants, UV stabilizers, and the like are optional in many embodiments and can be used at concentrations of from 0 to 30% or more, such as up to 40% in particular embodiments. In certain embodiments, the total amount of fillers (inorganic and/or organic), pigments, plasticizers, flame retardants, UV stabilizers, and combinations thereof is from 0.1% to 30%, and more particularly from 1% to 20%

The components of the adhesive formulation are combined in any suitable fashion such as by conventional blending techniques. The components are typically dispersed within the adhesive formulation and in most embodiments are uniformly dispersed or substantially so, throughout the adhesive formulation by mixing or blending. As previously noted one or more liquid vehicles can be incorporated into the formulation such as for example to promote dispersal of the components and/or to adjust the viscosity of the resulting formulation.

In many embodiments, the adhesive layer is exclusively a pressure sensitive adhesive and thus consists essentially of such adhesive(s). Although the present subject matter adhesive tapes generally utilize pressure sensitive adhesives, it is also contemplated that structural adhesives could be used.

In many embodiments of the present subject matter tapes, the adhesive layer and/or regions are free of electrically conductive particulates such as graphite flakes, powder, and/or fibers. And, in particular embodiments the adhesive layer and/or regions are free of other conductive agents such as metallic particles such as aluminum oxide, or titanium diborides or other boride compounds. And, in many versions of the present subject matter tapes, the adhesive layer and/or regions are generally not electrically conductive.

The adhesive tapes of the present subject matter may also include one or more additional layers and/or components. However, in many embodiments, the tapes consist exclusively of two layers that consist of a metal foil layer disposed immediately adjacent to an adhesive layer, or three layers that consist of a metal foil layer disposed immediately adjacent to and between two adhesive layers.

For single sided tapes, the adhesive layer has a thickness of from about 1 to 20 microns, and in particular embodiments less than 10 microns such as for example within a range of from 1 to 10 microns. In certain embodiments, it may be beneficial to utilize such relatively thin adhesive layers in order to reduce bulk thermal resistivity. However, it will be understood that the present subject matter is not limited to adhesive layers having these thicknesses. Thus, the present subject matter includes tapes having adhesive layers having a thickness less than 1 micron and/or greater than 20 microns.

For single sided tapes and in many embodiments of the present subject matter, the total thickness of the adhesive tape is within a range of from 10 microns to 30 microns and particularly from 6 microns to 25 microns. However, it will be appreciated that the present subject matter includes tapes having a thickness less than 10 microns and/or greater than 30 microns. These thickness values do not include any release liner(s) that may be provided.

For double sided tapes, at least one of the adhesive layers has a thickness of from about 1 to 20 microns, and in particular embodiments less than 10 microns such as for example within a range of from 2 to 10 microns. And in particular embodiments, each of the first and the second adhesive layers has a thickness less than 10 microns. In certain embodiments, it may be beneficial to utilize such relatively thin adhesive layers in order to reduce bulk thermal resistivity. However, it will be understood that the present subject matter is not limited to adhesive layers having these thicknesses. Thus, the present subject matter includes tapes having adhesive layers each having a thickness less than 1 micron and/or greater than 20 microns.

For double sided tapes and in many embodiments of the present subject matter, the total thickness of the adhesive tape is within a range of from 10 microns to 30 microns. However, it will be appreciated that the present subject matter includes tapes having a thickness less than 10 microns and/or greater than 30 microns. These thickness values do not include any release liner(s) that may be provided.

### Release Liner(s)

Many of the layered assemblies of the present subject matter comprise a release liner or layer that covers an otherwise exposed face of the adhesive layer. Typically, the release liner includes a layer of a silicone release agent that contacts the adhesive layer. A wide array of release liners can be used in the layered assemblies of the present subject matter. Commercially available release liners can be used such as those from Mitsubishi.

The adhesive tapes can utilize one, two, or more release liners. Generally, a single release liner is used to cover an adhesive layer. For versions of the tapes that utilize two or more regions of adhesive, the present subject matter includes the use of a single release liner disposed on the various regions of the adhesive layer. And, the subject matter includes the use of two or more release liners, each disposed on and covering one or more regions of the adhesive layer. The present subject matter also includes only covering a portion of the adhesive layer or region(s), and thereby leaving a portion of the adhesive layer or region(s) uncovered and exposed.

### Heat Spreader Assemblies

The present subject matter also provides various heat spreader assemblies that include (i) one or more thin, deformable heat conductive members and (ii) a single sided adhesive tape as described herein, and/or a double sided adhesive tape as described herein, or combinations thereof.

The thin, deformable or flexible heat conductive member is typically formed from materials with a relatively high in-plane thermal conductivity. Graphite is used for many applications. Aluminum, copper, and various composite materials have also been used. Typically, the thin, flexible heat conductive member is used to eliminate regions of relatively high temperature in electronic devices such as laptop computers and handheld smart phones. Many such heat conductive members have a thickness of from 50 microns to 1,000 microns or more, and particularly, within a range of from 100 microns to 750 microns.

The thin, deformable heat conductive member is typically in a sheet form and upon installation or use, may be shaped and/or sized for a particular application. The adhesive tape(s) can be used to adhere and affix the heat conductive member to a surface, component, or assembly of interest for which heat dissipation is desired. Typically, sections of the adhesive tape(s) are disposed between the surface, component, or assembly and the heat conductive member. In many applications, the double sided adhesive tapes are positioned between the surface, component, or assembly and the heat conductive member. In certain applications, the single sided adhesive tape is used to overlay or otherwise cover or at least partially cover the heat conductive member. These and other aspects are all described in greater detail herein.

A wide array of heat conductive members and particularly those in sheet form are commercially available and may be used in accordance with the present subject matter as described herein. Nonlimiting examples of commercially available sheet form members include AVCARB heat spreaders available from AvCarb Material Solutions of Lowell, Mass.; PGS Graphite Sheets available from Panasonic Electronic Devices, Co., Ltd.; T-WING and C-WING heat spreaders available from Chromerics of Parker Seals; IMCUTF-S Thermal Sheet available from Intermark USA, Inc. of San Jose, Calif.; and EGRAF SPREADERSHIELDS available from GrafTech International.

### Representative Embodiments of Tapes and Heat Spreader Assemblies

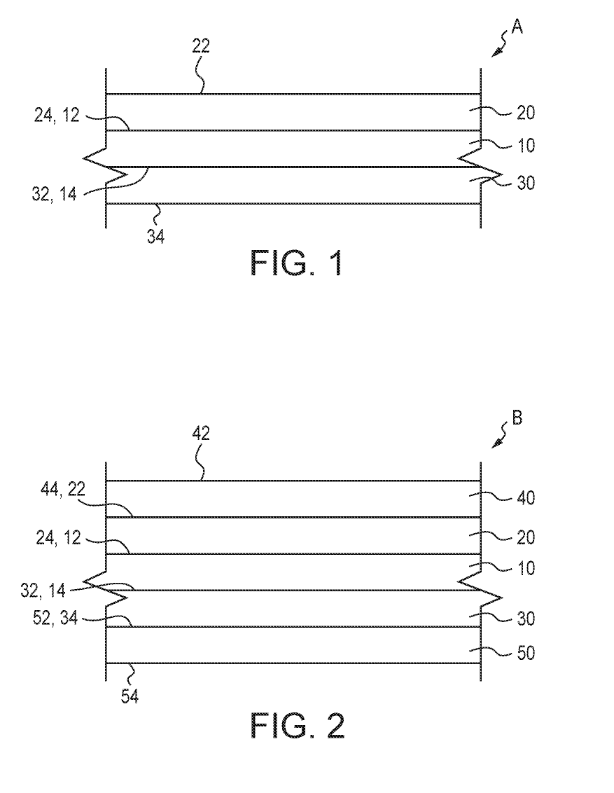

FIG. 1 schematically depicts an embodiment of a double sided adhesive tape A in accordance with the present subject matter comprising a metal foil layer 10, a first adhesive layer 20, and a second adhesive layer 30. The foil layer 10 defines a first face 12, and an oppositely directed second face 14. The first adhesive layer 20 defines a first face 22 and an oppositely directed second face 24. The second adhesive layer 30 defines a first face 32 and an oppositely directed second face 34. The first face 12 of the foil 10 is in contact with the second face 24 of the first adhesive layer 20, and the second face 14 of the foil 10 is in contact with the first face 32 of the second adhesive layer 30.

FIG. 2 schematically depicts another embodiment of a double sided adhesive tape B in accordance with the present subject matter. The tape B includes the previously described tape A of FIG. 1 with a first release liner 40 and a second release liner 50. Specifically, the first release liner 40 defines two oppositely directed faces 42 and 44, and is disposed on the first adhesive layer 20 such that the second face 44 is in contact with the first face 22 of the first adhesive layer 20. The second release liner 50 defines two oppositely directed faces 52 and 54, and is disposed on the second adhesive layer 30 such that the first face 52 is in contact with the second face 34 of the second adhesive layer 30.

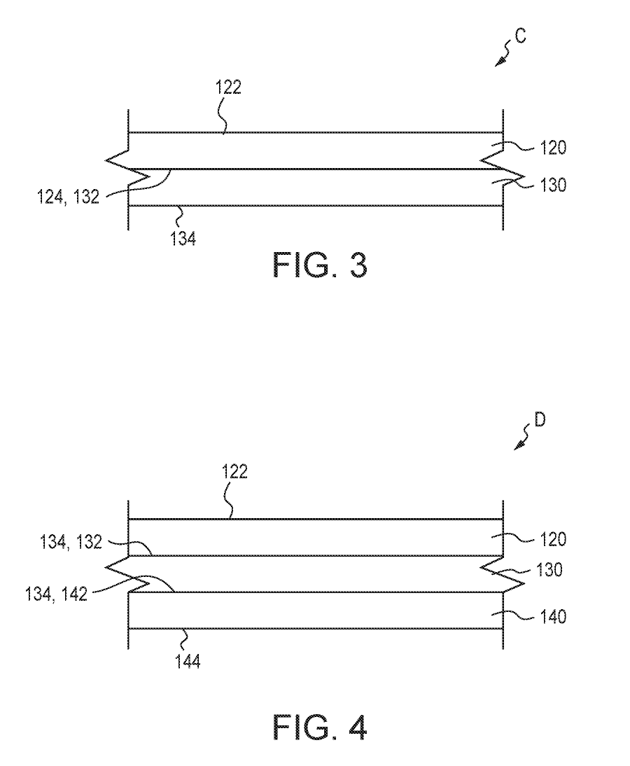

FIG. 3 schematically depicts an embodiment of a single sided adhesive tape C in accordance with the present subject matter comprising a metal foil layer 120, and an adhesive layer 130. The foil layer 120 defines a first face 122, and an oppositely directed second face 124. The adhesive layer 130 defines a first face 132 and an oppositely directed second face 134. The second face 124 of the foil 120 is in contact with the first face 132 of the adhesive layer 130.

FIG. 4 schematically depicts another embodiment of a single sided adhesive tape D in accordance with the present subject matter. The tape D includes the previously described tape C of FIG. 3 with a release liner 140. Specifically, the release liner 140 defines two oppositely directed faces 142 and 144, and is disposed on the adhesive layer 130 such that the first face 142 of the release liner 140 is in contact with the second face 134 of the adhesive layer 130.

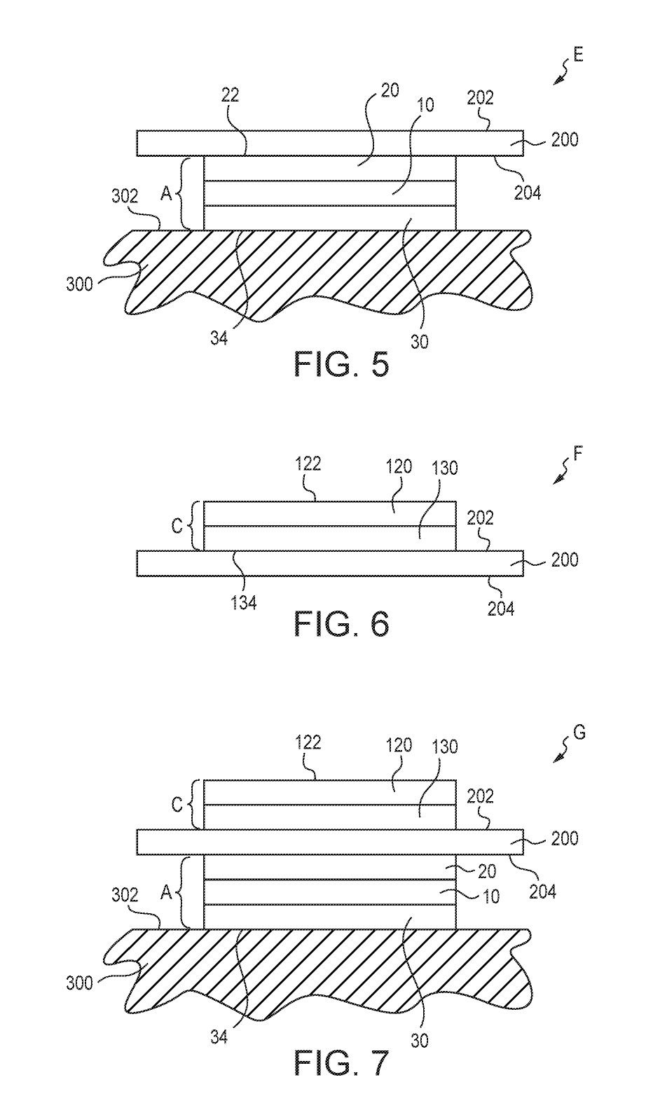

FIG. 5 schematically illustrates a heat spreader assembly E in accordance with an embodiment of the present subject matter. The heat spreader assembly E comprises a heat conductive member 200 which is typically in a sheet form, and a double sided adhesive tape A. The heat conductive member 200 defines oppositely directed faces 202 and 204. The double sided tape A is as previously described in conjunction with FIG. 1. The double sided tape A is disposed between the heat conductive member 200 and a surface, component or other assembly 300 for which heat dissipation or heat transfer is desired. The tape A serves to adhere and affix the heat conductive member 200 to a surface or face 302 of 300. An adhesive layer 20 of the tape A is contacted and adhered to the face 204 of the conductive member 200, and an adhesive layer 30 of the tape A is contacted and adhered to the face 302 of 300.

FIG. 6 schematically illustrates a heat spreader assembly F in accordance with another embodiment of the present subject matter. The heat spreader assembly F comprises a heat conductive member 200 as previously described in FIG. 5, and a single sided adhesive tape C as previously described in FIG. 3. An adhesive layer 130 of the tape C contacts and is adhered to the face 202 of the heat conductive member 200.

FIG. 7 schematically illustrates a heat spreader assembly G in accordance with another embodiment of the present subject matter. The heat spreader assembly G comprises a heat conductive member 200 as previously described in FIG. 5, a double sided adhesive tape A as described in FIG. 1, and a single sided adhesive tape C as described in FIG. 3. The double sided tape A adheres and affixes the heat conductive member 200 to a surface, component or assembly 300. The single sided tape C covers or at least partially covers the heat conductive member 200.

### Methods

The adhesive tapes are formed by deposition or coating of the adhesive formulation on a face or region(s) of the release liner. The adhesive coated release liner is then combined with the metal layer as described in greater detail herein. It is also contemplated that the adhesive could be coated or otherwise applied to the metal foil layer. The adhesive coated metal layer could then optionally be combined with a release liner. Nonlimiting examples of coating methods include slot die, meyer rod, air knife, brush, curtain, extrusion, blade, floating knife, kiss roll, knife-over-blanket, knife-over-roll, micro-gravure, gravure, offset gravure, reverse roll, reverse-smoothing roll, rod, and squeeze roll coating. In many embodiments of the present subject matter, the adhesive formulation is at least partially cured. Typically, curing or at least partial curing is performed or at least promoted by heating. However, the present subject matter also includes curing performed by exposure to radiant energy such as UV light and/or electron beam.

The adhesive tapes of the present subject matter can include one or more pattern coated adhesive regions. In certain embodiments it may be useful to pattern coat particular sections of the tapes to promote ease in removal.

Moreover, in use or prior to use, the adhesive tapes will likely be subjected to one or more die-cutting operations for subsequent conversion or use.

In certain versions of the present subject matter and particularly for single sided tapes, the adhesive coated release liner and the metal layer are combined in a dry lamination operation. Specifically, in this technique, the metal foil is contacted with an exposed face of the adhesive layer previously coated or otherwise applied to the release liner. This technique can be used with a wide array of adhesives, however pressure sensitive adhesives find particular applicability. The dry lamination technique can be performed at ambient temperatures and/or pressures. The present subject matter includes combining or laminating the metal and adhesive layers using elevated temperatures and/or pressures.

### Tape Form

The present subject matter adhesive tapes can be provided in a variety of forms such as in a roll form, a sheet form, or a Z-fold form. In many embodiments, the tapes are provided in a roll form.

### Additional Aspects

In certain versions of the tapes of the present subject matter, printability of the exposed face of the metal layer, such as faces 22, 42 in FIGS. 1 and 2, respectively, may be improved by exposing the tape and specifically the metal face of the tape to ambient air. Such exposure can result in oxidation of the metal face, which can promote printability of inks and coloring agents on the metal face.

### Applications

The present subject matter adhesive tapes can be used in a wide array of applications. For example, the tapes can be used in many applications in which it is desired to provide one or more of heat transfer, electrical conductivity, shielding from electromagnetic interference (EMI), shielding from radio frequency interference (RFI), and other factors. The tapes offer excellent thermal, mechanical, environmental, and chemical properties.

The present subject matter also provides methods of transferring heat or increasing heat transfer from one location to another location of lower temperature by applying a section of the tape described herein, between the two locations. In many applications, the adhesive tape is adhesively contacted with both locations and the inner metal foil layer transfers heat. The relatively thin adhesive layer does not significantly impede heat transfer through its thickness.

The present subject matter also provides various methods and techniques of transferring heat and particularly eliminating “hot spots” in electronic assemblies. The methods comprise providing a flexible heat conductive member as described herein. This may also include forming, sizing, and/or cutting the heat conductive member to a desired shape and/or size such as for example to overlay a region of interest in an electronic assembly. The heat conductive member can be affixed to the desired region by use of one or more sections of the double sided adhesive tapes described herein. Specifically, sections of double sided adhesive tape are positioned between the conductive member and the desired region to thereby adhere and retain the conductive member. Optionally, one or more sections or lengths of single sided adhesive tape can be positioned over all or portions of the conductive member to further adhere and retain the conductive member in place. The adhesive tape(s) contribute and promote heat transfer.

Many other benefits will no doubt become apparent from future application and development of this technology.

All patents, applications, standards, and articles noted herein are hereby incorporated by reference in their entirety.

The present subject matter includes all operable combinations of features and aspects described herein. Thus, for example if one feature is described in association with an embodiment and another feature is described in association with another embodiment, it will be understood that the present subject matter includes embodiments having a combination of these features.

As described hereinabove, the present subject matter solves many problems associated with previous strategies, systems and/or devices. However, it will be appreciated that various changes in the details, materials and arrangements of components, which have been herein described and illustrated in order to explain the nature of the present subject matter, may be made by those skilled in the art without departing from the principle and scope of the claimed subject matter, as expressed in the appended claims.

1. Adhesive tape comprising:
a metallic foil layer, the foil layer including at least one agent selected from the group consisting of aluminum, copper, gold, silver, beryllium, tungsten, alloys thereof, and combinations thereof, the foil layer defining a first face and an oppositely directed second face,
a layer of adhesive disposed on and immediately adjacent to the first face of the foil layer;
wherein the layer of adhesive is free of conductive agents.

2. (canceled)

3. The adhesive tape of claim 1 wherein the tape includes at least one release liner disposed on the layer of adhesive.

4. The adhesive tape of claim 3 wherein the tape includes a first release liner disposed on a first region of the layer of adhesive and a second release liner disposed on a second region of the layer of adhesive.

5. The adhesive tape of claim 1 wherein the layer of adhesive includes a pressure sensitive adhesive.

6. (canceled)

7. The adhesive tape of claim 1 wherein the layer of adhesive includes an acrylic adhesive.

8. (canceled)

9. The adhesive tape of claim 1 wherein the foil layer has a thickness of from 4 to 20 microns.

10. (canceled)

11. The adhesive tape of claim 1 wherein the layer of adhesive has a thickness of from 1 to 20 microns.

12. (canceled)

13. The adhesive tape of claim 1 wherein the tape is in a roll form.

14. The adhesive tape of claim 1, wherein
the foil layer disposed immediately adjacent to and in contact with the layer of adhesive exhibits a thermal conductivity greater than 100 W/mK at 25° C.

15. (canceled)

16. (canceled)

17. (canceled)

18. (canceled)

19. (canceled)

20. The adhesive tape of claim 14 wherein the foil layer has a thickness of from 4 to 20 microns.

21. (canceled)

22. (canceled)

23. (canceled)

24. (canceled)

25. A method of increasing heat transfer from a first location having a first temperature to a second location having a second temperature less than the first temperature, the method comprising:
providing an adhesive tape including (i) an inner metallic foil layer, the foil layer including at least one agent selected from the group consisting of aluminum, copper, gold, silver, beryllium, tungsten, alloys thereof, and combinations thereof, the foil layer defining a first face and an oppositely directed second face, and (ii) at least one layer of adhesive free of conductive agents and disposed on at least one face of the foil layer;
applying the adhesive tape on both of the first location and the second location.

26. (canceled)

27. The method of claim 25 wherein the layer of adhesive has a thickness of less than 10 microns.

28. A method of claim 25, wherein
the metallic foil layer exhibits a thermal conductivity greater than 100 W/mK at 25° C., the foil layer disposed immediately adjacent to the layer of adhesive and the foil layer in contact with the layer of adhesive, and the foil layer has a thickness within a range of from 4 microns to 15 microns.

29. (canceled)

30. The adhesive tape of claim 1 further comprising:
a second layer of adhesive disposed on a second face of the foil layer;
wherein a first layer of adhesive is disposed on the first face of the foil layer; and
wherein both the first layer of adhesive and the second layer of adhesive are free of conductive agents.

31. The adhesive tape of claim 30 wherein the tape consists of the foil layer disposed between the first layer of adhesive and the second layer of adhesive.

32. (canceled)

33. (canceled)

34. The adhesive tape of claim 30 wherein at least one of the first layer of adhesive and the second layer of adhesive include a pressure sensitive adhesive.

35. (canceled)

36. The adhesive tape of claim 30 wherein at least one of the first layer of adhesive and the second layer of adhesive include an acrylic adhesive.

37. (canceled)

38. The adhesive tape of claim 30 wherein the foil layer has a thickness of from 4 to 20 microns.

39. (canceled)

40. (canceled)

41. (canceled)

42. (canceled)

43. (canceled)

44. (canceled)

45. Adhesive tape of claim 30, wherein
the metallic foil layer exhibits a thermal conductivity greater than 100 W/mK at 25° C., the foil layer disposed between the first layer of adhesive and the second layer of adhesive and the foil layer in contact with both the first layer of adhesive and the second layer of adhesive; and
wherein each of the first layer of adhesive and the second layer of adhesive has a thickness less than 10 microns.

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. A heat spreader assembly comprising:
a heat conductive member defining a first face and an oppositely directed second face;
an adhesive tape including (i) a metallic foil layer, the foil layer including at least one agent selected from the group consisting of aluminum, copper, gold, silver, beryllium, tungsten, alloys thereof, and combinations thereof, the foil layer defining a first face and an oppositely directed second face, and (ii) a layer of adhesive disposed on and immediately adjacent to the first face of the foil layer,
wherein the layer of adhesive is free of conductive agents;
wherein the layer of adhesive of the adhesive tape is in contact with the first face of the heat conductive member.

68. (canceled)

69. (canceled)

70. (canceled)

71. (canceled)
